(19) United States
(12) Patent Application Publication
(10) Pub. No.: US 2005/0145405 A1
(43) Pub. Date: Jul. 7, 2005

(54) Electric member having shielding device

(76) Inventor: Chia Pang Chen, Taichung (TW)

Correspondence Address: Chia Pang Chen, P.O. Box 63-298, Taichung, 406, TW

(21) Appl. No.: 10/751,830

(22) Filed: Jan. 2, 2004

(51) Int. Cl. H05K 9/00

(52) U.S. Cl. 174/35 R

(57) ABSTRACT

An electric member includes an electric element, a housing having a chamber to receive the electric element, and a sealing member attached to the housing and engaged with the electric element to retain the electric element within the chamber of the housing. The housing is preferably made of ceramic materials to shield the electric element and to prevent an electromagnetic wave generated by the electric element from emitting out through the housing, and thus to prevent the electromagnetic wave from hurting the users, or to reduce the electromagnetic interference (EMI) problems.

### BACKGROUND OF THE INVENTION

1. Field of the Invention

The present invention relates to an electric member, and more particularly to an electric member having a shielding device or an anti-electromagnetic wave device for covering or shielding purposes and for reducing electromagnetic interference (EMI) problems.

2. Description of the Prior Art

Typical electric parts or elements, such as capacitors, resistors, inductors, etc., comprise a housing, an electric body received in the housing and having one or more prongs extended therefrom, for coupling to circuit boards, or other electric facilities.

Conventionally, the typical electric parts or elements may generate electromagnetic field while in use or when they are energized, and are attached to the circuit boards of various electric facilities, and may cause electromagnetic interference (EMI) problems.

For example, the mobile or portable phones have been widely used today, and are required to be disposed close to the ears of the users, and may generate strong electromagnetic waves that may seriously hurt the users.

Normally, the typical electric parts or elements have not been suitably covered or shielded by covering members, or have no anti-electromagnetic wave devices or shielding devices, to reduce the electromagnetic waves that may be generated by the typical electric parts or elements, such that the electromagnetic waves may be emitted out of the typical electric parts or elements, and may hurt the users.

The present invention has arisen to mitigate and/or obviate the afore-described disadvantages of the conventional electric elements.

### SUMMARY OF THE INVENTION

The primary objective of the present invention is to provide an electric member including an anti-electromagnetic wave device or a shielding device for covering or shielding purposes and for reducing electromagnetic interference (EMI) problems.

In accordance with one aspect of the invention, there is provided an electric member comprising an electric element, a housing having a chamber to receive the electric element, and a sealing member attached to the housing and engaged with the electric element to retain the electric element within the chamber of the housing. The housing is preferably made of ceramic materials to shield the electric element and to prevent an electromagnetic wave generated by the electric element from emitting out through the housing, and thus to prevent the electromagnetic wave from hurting the users, or to reduce the electromagnetic interference (EMI) problems.

The housing is made of ceramic materials. The housing includes a peripheral wall and an upper wall to form the chamber thereof and to receive the electric element in the chamber thereof.

The housing includes at least one projection extended into the chamber thereof, to engage with the electric element, and to form a peripheral channel between the electric element and the peripheral wall of the housing. The housing includes at least one depression formed by the projection, the sealing member includes a portion engaged into the depression of the housing.

The housing includes at least one recess formed in the upper wall thereof, to allow the electric element to be expanded relative to the housing.

The electric element includes a casing received in the chamber of the housing. The electric element includes at least one conductor received in the casing and having a prong extended out of the casing. The casing includes an open bottom, the electric element includes a covering member attached to the open bottom and engaged with the conductor, to retain the conductor in the casing.

The conductor includes an enlarged intermediate segment formed therein and engaged in the covering member, to stably secure the conductor to the casing with the covering member. The electric element includes a core received in the casing and engaged in the conductor.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a cross sectional view of an electric member in accordance with the present invention;

FIG. 2 is a perspective view of a shielding device or an anti-electromagnetic wave device for covering or shielding the typical electric elements and for reducing electromagnetic interference (EMI) problems; and

FIG. 3 is a cross sectional view of the electric element.

### DETAILED DESCRIPTION OF THE PREFERRED EMBODIMENT

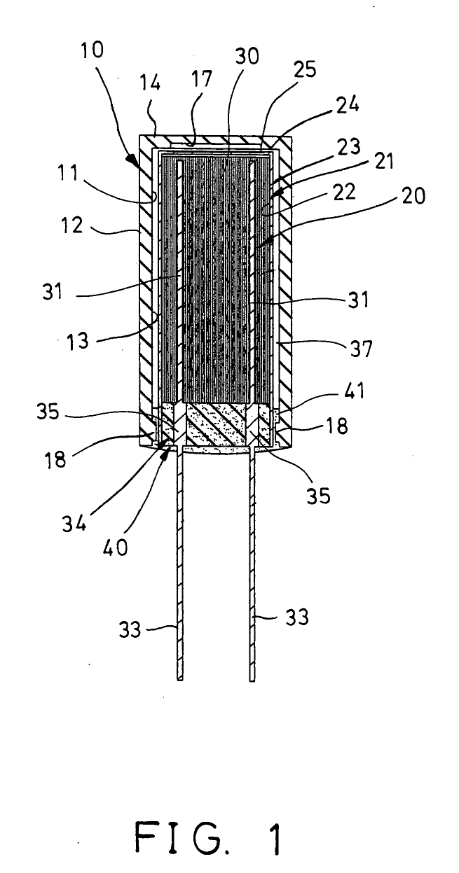

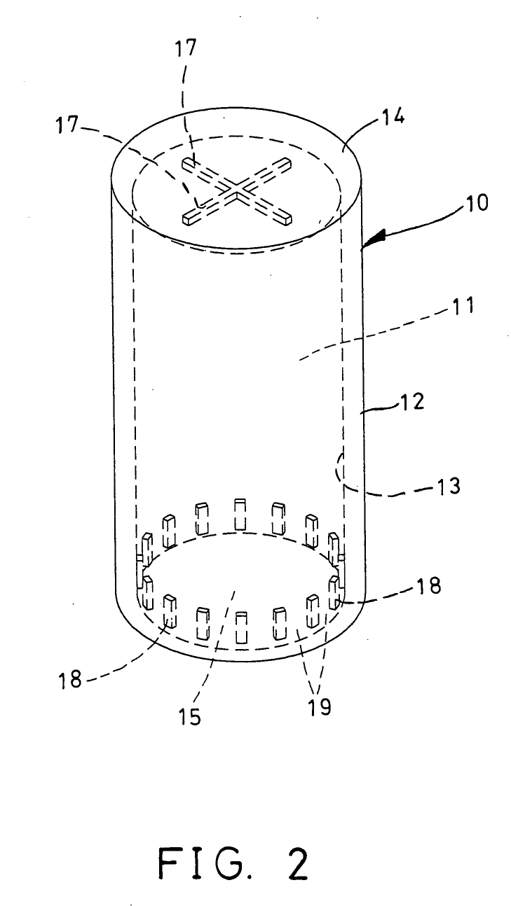

Referring to the drawings, and initially to FIGS. 1 and 2, an electric member in accordance with the present invention comprises a housing 10 made of such as ceramic materials, which is excellent for shielding electromagnetic waves, and which is heat conductive for allowing heat to be dissipated through the ceramic housing 10.

The housing 10 includes a chamber 11 formed therein and defined by an inner peripheral surface 13 of a cylindrical or peripheral wall 12, and an upper wall 14, and includes an opening 15 formed in the other or the lower portion thereof for receiving an electric element 20 therein, such as capacitors, resistors, inductors, etc., for shielding the electric element 20.

It is preferable that the housing 10 includes a one or more recesses 17 formed therein, such as formed in the upper wall 14, and communicating with the chamber 11 thereof, and includes one or more projections 18 extended into the chamber 11 thereof, and preferably arranged or located close to the opening 15 thereof, to form or define one or more depressions 19 between the projections 18.

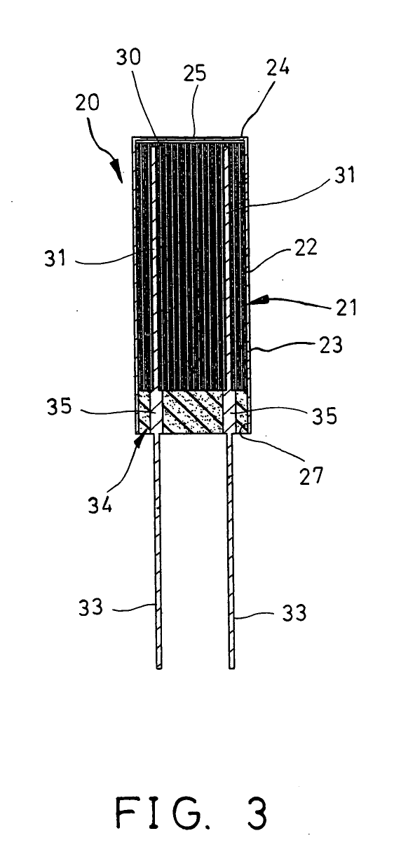

As shown in FIGS. 1 and 3, the electric element 20 includes a casing 21 having a space 22 formed therein and defined by a cylindrical or peripheral fence 23 and an upper panel 24, and includes an open bottom 27, in which the upper panel 24 preferably includes one or more grooves 25 formed therein.

The electric element 20 includes an electric body or a core 30 received in the space 22 of the casing 21, and one or more conductors 31 engaged in the core 30 and having one or more prongs 33 extended out of the casing 21, for coupling to circuit boards (not shown), or other electric facilities (not shown).

A covering member 34 is applied or engaged into the open bottom 27 of the casing 21, to enclose the open bottom 27 of the casing 21, and to retain the core 30 and the conductors 31 within the space 22 of the casing 21, and thus to form the electric element 20. For example, the electric element 20 is shown as a capacitor in FIGS. 1 and 3.

Each of the conductors 31 preferably includes an enlarged intermediate segment 35 formed therein and engaged in the covering member 34, for allowing the conductors 31 to be stably secured to the casing 21 with the covering member 34.

The casing 21 of the electric element 20 is then engaged into the chamber 11 of the housing 10, and engaged or disposed in the projections 18 of the housing 10, such that the casing 21 may be spaced away from the inner peripheral surface 13 of the housing 10 for a distance, in order to form an annular or peripheral channel 37 between the casing 21 and the peripheral wall 12 of the housing 10.

An adhesive member or a resilient sealing member 40 is then applied onto the opening 15 of the housing 10, and engaged with the electric element 20, such as engaged with the covering member 34 of the electric element 20, to secure and retain the electric element 20 within the housing 10.

It is preferable that the resilient sealing member 40 includes a peripheral portion 41 engaged into the depressions 19 that are formed or defined between the projections 18 of the housing 10, to further stably and resiliently retain the electric element 20 within the housing 10. The prongs 33 that are extended out of the casing 21 are also extended out of the housing 10.

While in use or when the electric element 20 is energized, the electric element 20 may generate electromagnetic waves and may also generate heat, and may thus have internal stresses, thermal expansion displacements, or heat dissipation problems generated or occurred.

The provision or the formation of the recesses 17 in the upper wall 14 of the housing 10 and/or the provision or the formation of the grooves 25 in the upper panel 24 of the casing 21 and/or the provision or the formation of the peripheral channel 37 formed between the casing 21 and the peripheral wall 12 of the housing 10 permits the electric element 20 to be slightly expanded.

In addition, the sealing member 40 is made or rubber or resilient materials and may also be expanded or stretched, for further allowing the electric element 20 to be expanded relative to the housing 10.

It is to be noted that the housing 10 is made of ceramic materials which include a close-packed structure that is heat conductive or that includes an excellent thermal conductivity. In addition the ceramic housing 10 is also excellent for shielding electromagnetic waves that may be generated by the electric element 20, in order to reduce the electromagnetic interference (EMI) problems.

When the electric element 20 are secured or attached onto the circuit boards or other electric facilities, the ceramic housing 10 may shield the electromagnetic waves that may be generated by the electric element 20, such that the circuit boards or the other electric facilities are not required to provide the other anti-electromagnetic wave device to cover or shield the electric element 20.

Accordingly, the electric member in accordance with the present invention includes an anti-electromagnetic wave device or a shielding device for covering or shielding purposes and for reducing electromagnetic interference (EMI) problems.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

1. An electric member comprising:
an electric element,
a housing including a chamber formed therein to receive said electric element therein and to shield said electric element and to prevent an electromagnetic wave generated by said electric element from emitting out through said housing, and
a sealing member attached to said housing, and engaged with said electric element, to retain said electric element within said chamber of said housing.

2. The electric member as claimed in claim 1, wherein said housing is made of ceramic materials.

3. The electric member as claimed in claim 1, wherein said housing includes a peripheral wall and an upper wall to form said chamber thereof and to receive said electric element in said chamber thereof.

4. The electric member as claimed in claim 3, wherein said housing includes at least one projection extended into said chamber thereof, to engage with said electric element, and to form a peripheral channel between said electric element and said peripheral wall of said housing.

5. The electric member as claimed in claim 4, wherein said housing includes at least one depression formed by said at least one projection, said sealing member includes a portion engaged into said at least one depression of said housing.

6. The electric member as claimed in claim 3, wherein said housing includes at least one recess formed in said upper wall thereof, to allow said electric element to be expanded relative to said housing.

7. The electric member as claimed in claim 1, wherein said electric element includes a casing received in said chamber of said housing.

8. The electric member as claimed in claim 7, wherein said electric element includes at least one conductor received in said casing and having a prong extended out of said casing.

9. The electric member as claimed in claim 8, wherein said casing includes an open bottom, said electric element includes a covering member attached to said open bottom and engaged with said at least one conductor, to retain said at least one conductor in said casing.

10. The electric member as claimed in claim 9, wherein said at least one conductor includes an enlarged intermediate segment formed therein and engaged in said covering member, to stably secure said at least one conductor to said casing with said covering member.

11. The electric member as claimed in claim 7, wherein said electric element includes a core received in said casing and engaged in said at least one conductor.
